(19) United States
(12) Patent Application Publication
(10) Pub. No.: US 2003/0045138 A1
(43) Pub. Date: Mar. 6, 2003

(54) Connector having high density terminals arrangement

(75) Inventors: Bay Shao-Ru Su, Bothell, WA (US); Chen Yu Timothy Yu, Taoyuan Shien (TW); Kun-Feng Chen, Taoyuan Shien (TW); Szu-Lu Huang, Taoyuan Shien (TW)

Correspondence Address: HAVERSTOCK & OWENS LLP, 162 North Wolfe Road, Sunnyvale, CA, 94086, US

(73) Assignee: Delta Electronics, Inc.

(21) Appl. No.: 10/225,220

(22) Filed: Aug. 20, 2002

(30) Foreign Application Priority Data
Aug. 31, 2001 (TW) 090215022

(51) Int. Cl. H05K 1/00

(52) U.S. Cl. 439/79

(57) ABSTRACT

A connector having a relatively high terminal density is provide for reducing the requirement of the electric currents in one signal terminal and increase the conducting efficiency. The connector includes plural first conducting components each having a first terminal and extended laterally, plural second conducting components each having at least two second terminals and extended laterally, and an insulating housing having plural slots for mounting the plural first conducting components and the plural second conducting components, wherein each first conducting component and each corresponding second conducting component are mounted in the respective slot, so as to contain a contact pad having plural pins.

### FIELD OF THE INVENTION

The present invention relates to a pin connector, and more particularly to a connector having a relatively high terminal density.

### BACKGROUND OF THE INVENTION

Referring to FIG. 1, it illustrates a typical PCB connector including an insulating housing 10. Meanwhile, the insulating housing 10 has a slot 11 for containing plural contact pads composed of plural pins, and plural conducting components 12 extended laterally from two sides of the slots 11. Each of said conducting components 12 further includes a terminal 13. FIG. 2 and FIG. 3 illustrate a terminal 13 of the conducting component 12. The terminal 13, a sliced-shaped conducting structure, has a contacting element 131, a connecting element 132 and a combining element 133. The contacting element 131 has a curved structure for conducting with said contact pad, so as to transmit the current and the signals. The connecting element 132 is connected to said insulating housing 10. The combining element 133 is mounted on a PCB.

Referring to FIGS. 4(a)-(c), they illustrate a single terminal 13 of the typical PCB connector. The terminal 13 is sheet-shaped, thereby the surface area of the connecting element 132 of the terminal 13 is used for conducting. The connecting element 132 further includes a concave 1321 for enhancing the connecting effect of the insulating housing 10 and the terminal 13 while the insulating housing 10 is molded. Therefore, the conducting component 12 is limited in response to the size of the surface area of the terminal 13 and one pin 13 can be disposed on each conducting component 12 merely.

Moreover, a typical PCB connector is usually used for transmitting the power and the signal in the same time, and the contacting region includes plural power pins and plural signal pins. Shown as FIG. 3, one terminal 13 of the PCB connector merely contacts and conducts with one of the power pins or the signal pins. Therefore the amount of the conducting component 12 is equal to the total amount of the signal pins and the power pins.

However, the requirement of the electric currents of a power pin is more than that of a signal pin while contacted with the PCB connector. The above conducting component 12 merely can transmit the signal or the power from one pin. In contacting pad, the size and the width of a power pin is the same as that of a signal pin. Therefore, the number of the conducting components 12 occupied by the power pins is fixed, and so is that occupied by the signal pins. While the total number of the conducting components is fixed and the number of the power pins in the contacting pad can't be increased, each terminal has to provide an electric current exceeding the requirement of a signal pin. Meanwhile, almost of the electric current is thrown away in a terminal contacting with the signal pin. The resistance of a signal terminal passing a large electric current therethrough will be increased and the power of the PCB connector will lose, thereby the conductivity is not good.

Accordingly, the PCB connector of the prior art has the following defects:

1. Each conducting component merely contains a signal terminal.

2. The signal pins and the power pins both occupy the same space and electric currents of the conducting component.

3. Each signal terminal has high-density electric current.

4. Each signal terminal has large resistance.

5. The power loss of the PCB connector is much more.

6. The conductivity of the typical PCB connector is not good.

Hence, the present invention improves the prior art and provides a PCB connector having a relatively high terminal density, so as to reduce the requirement of the electric currents in one signal terminal and increase the conducting efficiency.

### SUMMARY OF THE INVENTION

It is one object of the present invention to provides a PCB connector having a relatively high terminal density, so as to reduce the requirement of the electric currents in one signal terminal and increase the conducting efficiency.

According to the present invention, a connector having a relatively high terminal density includes plural first conducting components each having a first terminal and extended laterally, plural second conducting components each having at least two second terminals and extended laterally, and an insulating housing having plural slots for mounting the plural first conducting components and the plural second conducting components, wherein each first conducting component and each corresponding second conducting component are mounted in the respective slot, so as to contain a contact pad having plural pins.

Preferably, each of the plural second conducting components further includes an insulating partition disposed between the at least two second terminals.

Preferably, each second terminal further includes a contacting part for electrically conducting with the contact pad, a fastening part and a connecting part.

Certainly, the connecting part can be plugged into a main printed circuit board.

Certainly, the fastening part can be sheet-shaped and disposed vertically along a side of the insulating partition.

Preferably, the fastening part further includes an extended hook for fastening with the insulating housing.

Preferably, the fastening part further includes a trough for filling plastics therein while the insulating housing is molded.

Preferably, the second terminals and the insulating partitions are of a unity.

Certainly, ends of said at least two second terminals can be arranged alternately in front and back positions.

Certainly, the plural first conducting components and the plural second conducting components are of a unity.

According to the present invention, a connector for containing a contact pad having plural pins includes a first extended apparatus having plural first conducting components extended laterally and plural second conducting components extended laterally, a second extended apparatus having plural third conducting components extended laterally and plural fourth conducting components extended laterally, wherein the first extended apparatus and the second extended apparatus form a slot for containing the contact pad having plural pins, each first conducting component and each third conducting component include a first terminal and a third terminal respectively, and each second conducting component and each fourth conducting component include at least two second terminals and two fourth terminals respectively, and an insulating housing for containing the first extended apparatus and the second extended apparatus.

Certainly, the first extended apparatus, the second extended apparatus and the insulating housing can be of a unity.

Preferably, each of the plural second conducting components and the plural fourth conducting components further includes an insulating partition disposed between the at least two second terminals and two fourth terminals respectively.

Preferably, each of second terminals and fourth terminals further includes a contacting part for electrically conducting with the contact pad, a fastening part and a connecting part respectively.

Certainly, the connecting part can be plugged into a main printed circuit board.

Certainly, the fastening part can be sheet-shaped and disposed vertically along a side of said insulating partition.

Preferably, the fastening part further includes an extended hook for fastening with the insulating housing.

Preferably, the fastening part further includes a trough for filling plastics therein while the insulating housing is molded.

Certainly, the second terminals, the fourth terminals and the insulating partitions can be of a unity.

Certainly, ends of the at least two second terminals and fourth terminals can be arranged alternately in front and back positions respectively.

Certainly, the terminal and the second terminal can be of the same size essentially and the first terminal conduct more electric currents than the second terminal does.

Certainly, the third terminal and the fourth terminal can be of the same size essentially and the third terminal conduct more electric currents than said fourth terminal does.

According to the present invention, a connector having a relatively high terminal density includes an insulating housing having a slot for containing plural pins of a contact pad including plural pins, plural first conducting components extended laterally along a first side of the slot and plural second conducting components extended laterally along a second side of said slot, wherein each first conducting component includes a first terminal and each second conducting component includes at least two second terminals, and the first terminal and the second terminal of the same size essentially and the first terminal conducts more electric currents than the second terminal does.

Now the foregoing and other features and advantages of the present invention will be more clearly understood through the following descriptions with reference to the drawings, wherein:

### BRIEF DESCRIPTION OF THE DRAWINGS

FIG. 1 schematically depicts a connector of the prior art;

FIG. 2 depicts a cross-sectional view along 2-2′ of FIG. 1;

FIG. 3 depicts a lateral view of FIG. 2;

FIG. 4 (a) depicts a vertical view of a single terminal;

FIG. 4 (b) depicts an upward view of FIG. 4 (a);

FIG. 4 (c) depicts a lateral view of FIG. 4 (a);

FIG. 5 (a) depicts a structure of a corresponding second conducting component of a connector having a relatively high terminal density according to the present invention;

FIG. 5 (b) depicts a perspective drawing of the second conducting component of FIG. 5 (a);

FIG. 6 depicts the relative positions of the second conducting components of FIGS. 5 (a)-5 (b); and

FIG. 7 depicts a connector having a relatively high terminal density of the present invention and plugged in a PCB.

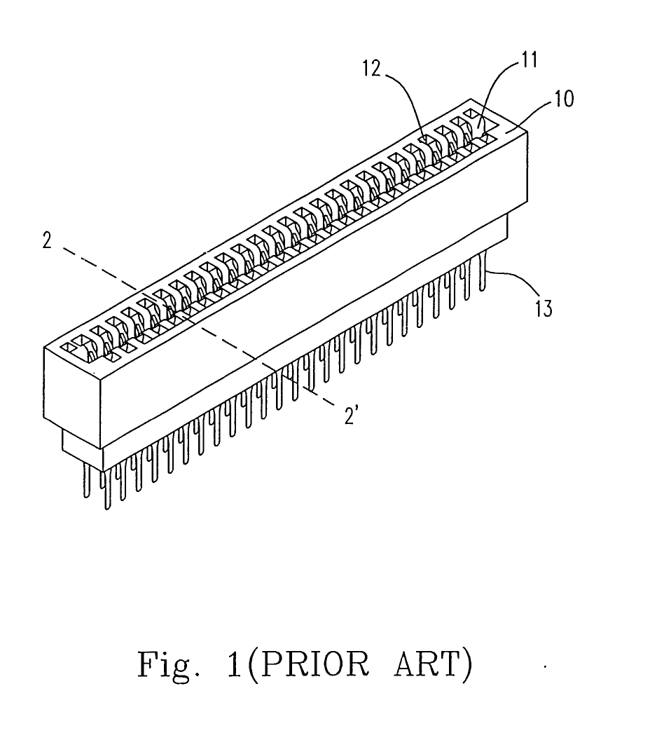

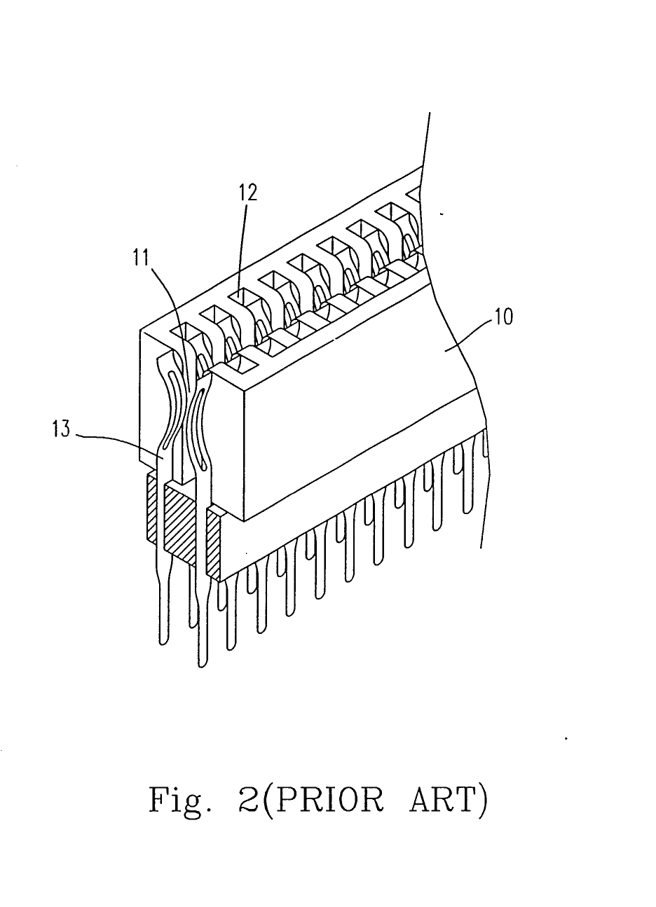

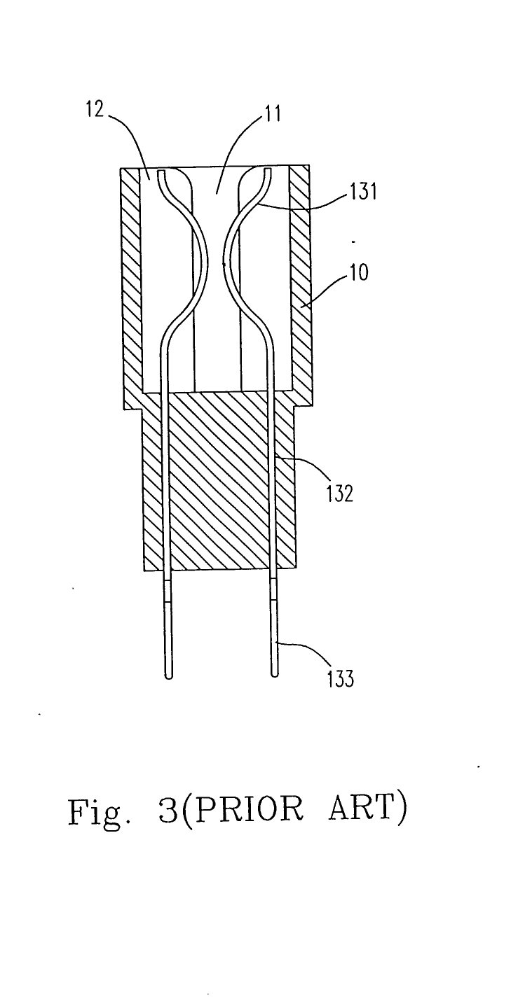

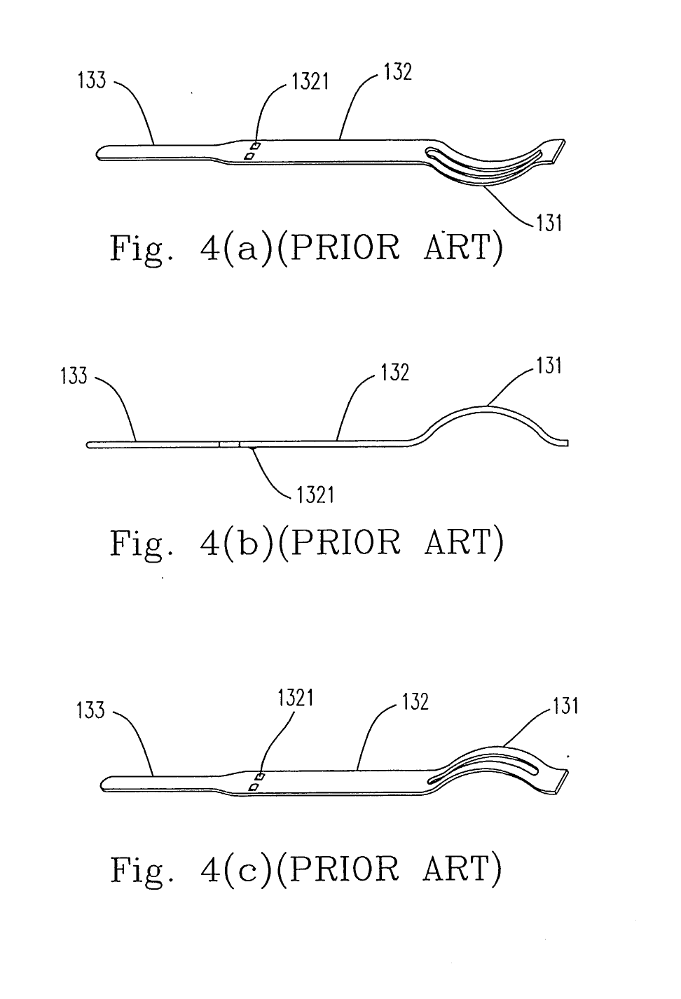

### DETAILED DESCRIPTION OF THE PREFERRED EMBODIMENT

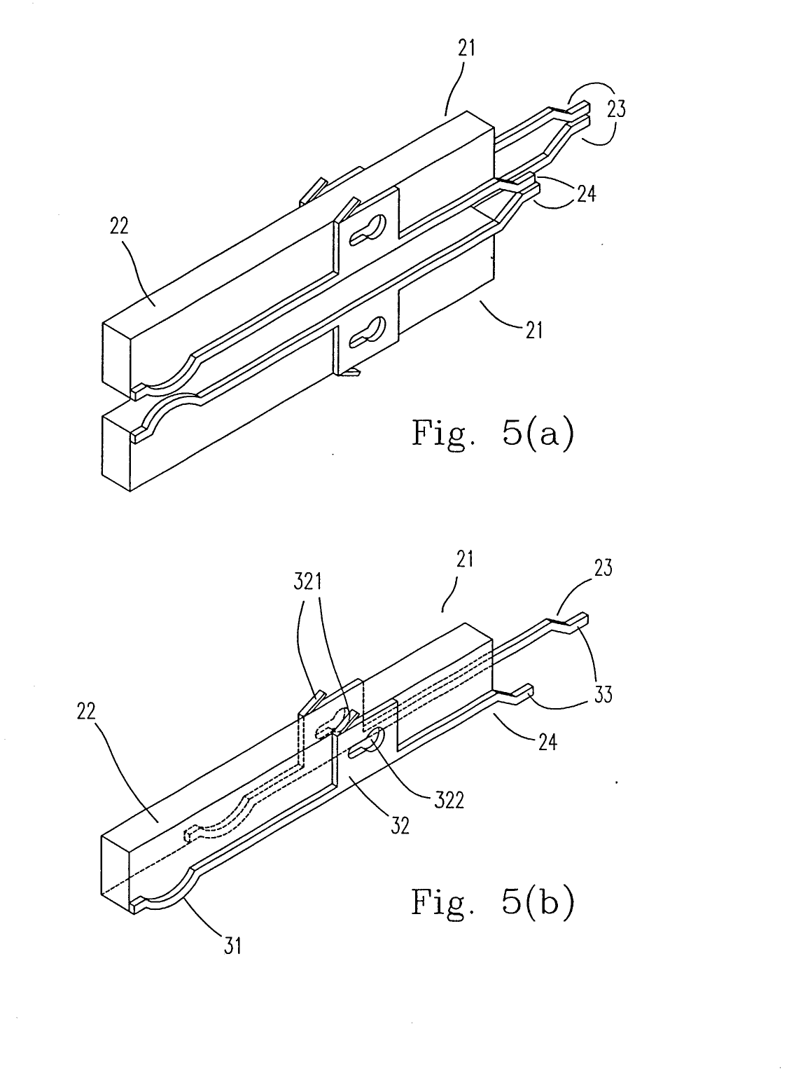

Referring to FIG. 5 (a), it illustrates a structure of a corresponding second conducting component of a connector having a relatively high terminal density according to the present invention. The connector having a relatively high terminal density includes plural first conducting components each having a first terminal and extended laterally, plural second conducting components 21 each having at least two second terminals 23, 24 and extended laterally, and an insulating housing having plural slots for mounting the plural first conducting components and the plural second conducting components, wherein each first conducting component and each corresponding second conducting component 21 are mounted in the respective slot, so as to contain a contact pad having plural pins. Meanwhile, the terminal and the second terminal are of the same size essentially and the first terminal conducts more electric currents than the second terminal does 23, 24. Furthermore, the plural first conducting components and the plural second conducting components 21 are of a unity and mounted in the insulating housing.

Referring to FIG. 5 (a), it illustrates two second terminals 23, 24 of a single second conducting component. Meanwhile, each of plural first conducting components has a first terminal, and each of plural second conducting components 21 has at least two second terminals 23, 24 and further includes an insulating partition 22 disposed between the at least two second terminals 23, 24. Therefore, one first terminal can conduct more electric currents than one second terminal 23, 24 does. According the above description, the at least two second terminals 23, 24 of a second conducting component can contact with two signal pins for conducting and the single first terminal of a first conducting component can contact with a single power pin for conducting.

Accordingly, the present invention improves the prior art. A typical connector has two corresponding conducting components of the same size. The total number of the conducting components is fixed and the number of the power terminals contacted with the contacting pad can't be increased. However in the present invention, the total number of terminals can be increased by means of respectively adding the number of terminals of one conducting component instead of changing the total number of the conducting components. In the embodiment of the present invention, a second conducting component can contact with at least two signal pins of the requirement of the lower current in the same time, and then the number of the second components occupied by signal pins can be reduced. Moreover, a single terminal of the first component contacts with the power pin of the requirement of the higher current. Therefore, the number of the conducting components occupied by the signal pins can be reduced in a connector having the conducting components of the same size, and the remaining conducting components can be used for contacting with the power pins, so as to reduce the requirement of the electric current in a single terminal, the resistance and the power loss. Each second conducting component in the embodiment of the present invention has two terminals. Certainly, each second conducting component of the present invention can have more than two terminals or be disposed flexibly in response to the different requirement. In one second conducting component having at least two second terminals, there is an insulating partition 22 corresponding to the number of at least two second terminals and disposed between the at least two second terminals. Each second terminal 23, 24 of a single conducting component 21 further includes a contacting part 31 for electrically conducting with the contact pad, a fastening part 32 and a connecting part 33. The connecting part 33 can be plugged into a main printed circuit board. The fastening part 32 can be sheet-shaped and disposed vertically along a side of the insulating partition 22. Furthermore, the fastening part 32 further includes an extended hook 321 for fastening with the insulating housing and a trough 322 for filling plastics therein while the insulating housing is molded. While fabricating the connector, the second terminals 23, 24 and the insulating partitions 22 are of a unity. Then they are plugged into the slot one by one to form the second conducting components 21.

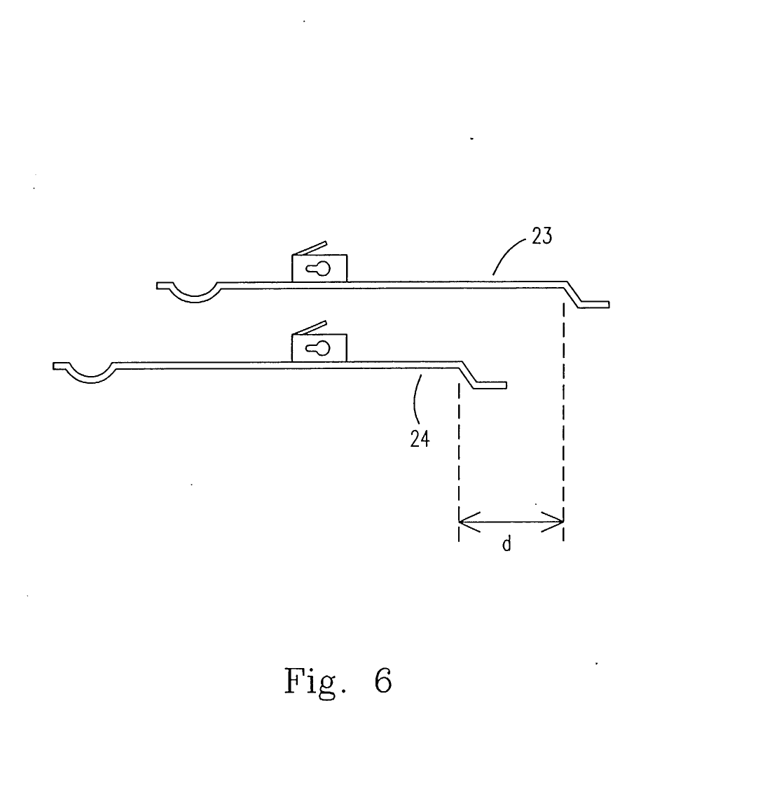

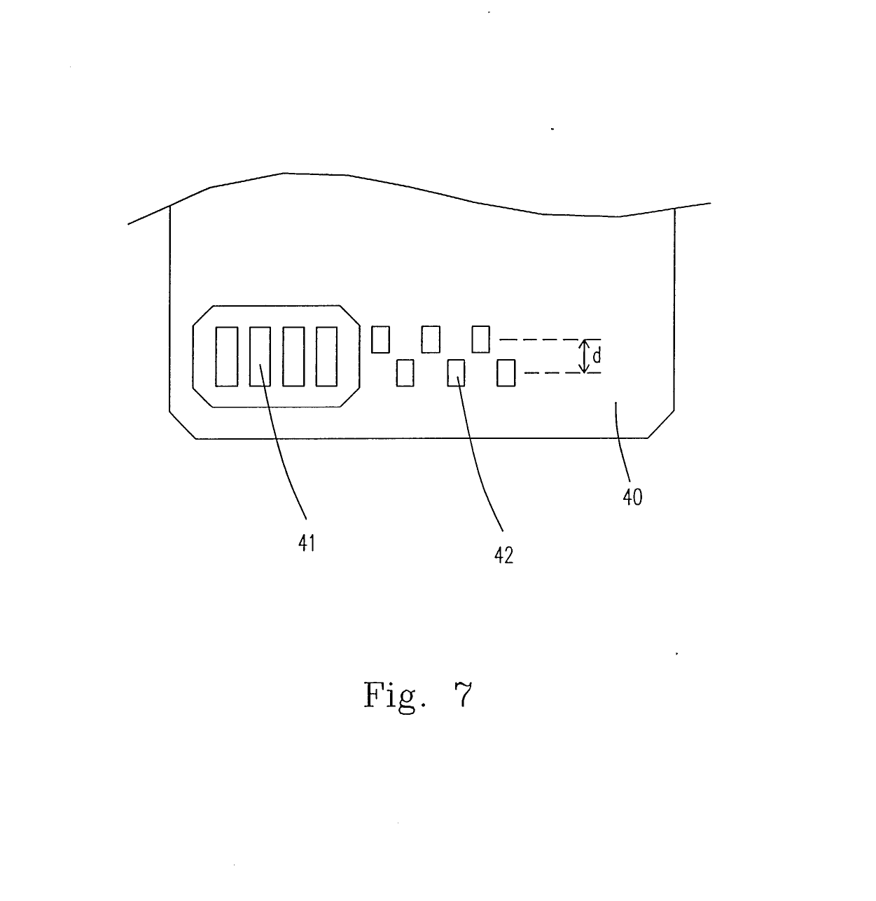

Referring to FIG. 6, two ends of the two second terminals 23 and 24 can be arranged alternately in front and back positions with a difference of distance d, so as to improve the layout of the circuit. Further referring to FIG. 7, a connector having a relatively high terminal density of the embodiment according to the present invention is plugged into a main PCB 40. Meanwhile, there are some alternate signal pins 42 and some abreast power pins 41 disposed on the main PCB 40. According to the above description, two ends of the two second terminals 23 and 24 can be arranged alternately in front and back positions with a difference of distance d. Hence the alternated signal pins 42 can be arranged alternately with a difference of distance d, so as to improve the layout of the circuit in the main PCB 40. Certainly, two ends of the two second terminals 23 and 24 can be arranged abreast in response to the design of the connector, and both of the alternate signal pins 42 and the abreast power pins 41 of FIG. 7 can be arranged abreast.

Accordingly, the present invention provides a connector having corresponding conducting components, which is designed in response to the number of the different pins in a contact pad. Usually, a PCB is designed to have a layout of plural double-layer contact pads arranged up and down for saving space and stuff. The double-layer contact pads have different layouts of several kind pins. In the embodiment of the present invention, a connector corresponding to the layout of the double-layer pads is provide, wherein the connector has plural conducting components. The plural conducting components are arranged adjustably and the kinds of the plural conducting components of two sides in the slot are not limited to correspond with each other. The first conducting components and the second conducting components of the present invention can be arranged adjustably in response to the layout of the contact pads contained by them. Hence the first conducting components and the second conducting components are not limited to only by terms of correspondence with each other.

Although the present invention has been described and illustrated in detail, it is to be clearly understood that the same is by the way of illustration and example only and is not to be taken by way of limitation, the spirit and scope of the present invention being limited only by the terms of the appended claims.

What is claimed is:

1. A connector having a relatively high terminal density comprising:
plural first conducting components each having a first terminal and extended laterally;
plural second conducting components each having at least two second terminals and extended laterally; and
an insulating housing having plural slots for mounting said plural first conducting components and said plural second conducting components, wherein said each plural first conducting component and said each corresponding plural second conducting component are mounted in said respective slot, so as to contain a contact pad having plural pins.

2. The connector according to claim 1, wherein each of said plural second conducting components further comprises an insulating partition disposed between said at least two second terminals.

3. The connector according to claim 2, wherein each said second terminal further comprises a contacting part for electrically conducting with said contact pad, a fastening part and a connecting part.

4. The connector according to claim 3, wherein said connecting part is plugged into a main printed circuit board.

5. The connector according to claim 3, wherein said fastening part is sheet-shaped and disposed vertically along a side of said insulating partition.

6. The connector according to claim 5, wherein said fastening part further comprises an extended hook for fastening with said insulating housing.

7. The connector according to claim 3, wherein said fastening part further comprises a trough for filling plastics therein while said insulating housing is molded.

8. The connector according to claim 2, wherein said second terminals and said insulating partitions are of a unity.

9. The connector according to claim 1, wherein ends of said at least two second terminals are arranged alternately in front and back positions.

10. The connector according to claim 1, wherein said plural first conducting components and said plural second conducting components are of a unity.

11. A connector for containing a contact pad having plural pins, comprising:
a first extended apparatus having plural first conducting components extended laterally and plural second conducting components extended laterally;
a second extended apparatus having plural third conducting components extended laterally and plural fourth conducting components extended laterally, wherein said first extended apparatus and said second extended apparatus form a slot for containing said contact pad having plural pins, each said first conducting component and each said third conducting component include a first terminal and a third terminal respectively, and each said second conducting component and each said fourth conducting component include at least two second terminals and two fourth terminals respectively; and
an insulating housing for containing said first extended apparatus and said second extended apparatus.

12. The connector according to claim 11, wherein said first extended apparatus, said second extended apparatus and said insulating housing are of a unity.

13. The connector according to claim 11, wherein each of said plural second conducting components and said plural fourth conducting components further comprises an insulating partition disposed between said at least two second terminals and two fourth terminals respectively.

14. The connector according to claim 13, wherein each of said second terminals and each said fourth terminals further comprise a contacting part for electrically conducting with said contact pad, a fastening part and a connecting part respectively.

15. The connector according to claim 14, wherein said connecting part is plugged into a main printed circuit board.

16. The connector according to claim 14, wherein said fastening part is sheet-shaped and disposed vertically along a side of said insulating partition.

17. The connector according to claim 14, wherein said fastening part further comprises an extended hook for fastening with said insulating housing.

18. The connector according to claim 14, wherein said fastening part further comprises a trough for filling plastics therein while said insulating housing is molded.

19. The connector according to claim 13, wherein said second terminals, said fourth terminals and said insulating partitions are of a unity.

20. The connector according to claim 11, wherein ends of said at least two second terminals and fourth terminals are arranged alternately in front and back positions respectively.

21. The connector according to claim 11, wherein said first terminal and said second terminal are of the same size essentially and said first terminal conducts more electric currents than said second terminal does.

22. The connector according to claim 11, wherein said third terminal and said fourth terminal are of the same size essentially and said third terminal conducts more electric currents than said fourth terminal does.

23. A connector having a relatively high terminal density comprising:
an insulating housing having a slot for containing plural pins of a contact pad including plural pins, plural first conducting components extended laterally along a first side of said slot and plural second conducting components extended laterally along a second side of said slot, wherein each said first conducting component includes a first terminal and each said second conducting component includes at least two second terminals, and said first terminal and said second terminal of the same size essentially and said first terminal conducts more electric currents than said second terminal does.
